(19) United States
(12) Patent Application Publication
(10) Pub. No.: US 2010/0277168 A1
(43) Pub. Date: Nov. 4, 2010

(54) MULTI-CHANNEL TEM COILS WITH AUXILIARY DECOUPLING ELEMENTS

(75) Inventor: Kai-Michael Luedeke, Hamburg (DE)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., EINDHOVEN (NL)

(21) Appl. No.: 12/747,536

(22) PCT Filed: Dec. 19, 2008
(86) PCT No.: PCT/IB08/55443

§ 371 Date: Jun. 11, 2010

(30) Foreign Application Priority Data
Dec. 19, 2007 (EP) 07123651.7

(51) Int. Cl. G01R 33/34; G01R 33/44

(52) U.S. Cl. 324/307; 324/318

(57) ABSTRACT

A radio frequency coil (30) includes a radio frequency screen (34), a plurality of operative TEM elements (35) defined by parallel elongate conductive elements (36) coupled with the radio frequency screen and configured for operative connection with a multi-channel radio frequency driver (32), and a plurality of auxiliary elongate conductive elements (40, 50, 60, 70, 80a, 80b). Each auxiliary elongate conductive element is arranged parallel with and between two neighboring operative TEM elements and tuned to substantially decouple the two neighboring operative TEM elements, there being an auxiliary elongate conductive element disposed between each two neighboring operative TEM elements.

### FIELD OF THE INVENTION

The following relates to the magnetic resonance arts. The following finds illustrative application to magnetic resonance imaging and spectroscopy, and is described with particular reference thereto. However, the following will find application in other magnetic resonance and radio frequency applications.

### BACKGROUND OF THE INVENTION

The magnetic resonance frequency and free space wavelength depends upon the static (B₀) magnetic field (also known as the main magnetic field), and in particular the free space wavelength decreases with increasing magnetic field. At high magnetic field (e.g., about 3 Tesla or higher) the relatively short free space wavelength can introduce substantial spatial nonuniformity in the radio frequency excitation that can be provided by a conventional quadrature-driven volume coil such as a birdcage or TEM coil.

Accordingly, as the magnetic resonance industry has moved toward higher magnetic field, such as for example magnetic resonance scanners operating at 7 Tesla, there has been interest in multichannel coils comprising multiple conductors that are separately driven. In a multichannel coil, the different driving radio frequency signals can be adjusted to provide better spatial uniformity.

However, inductive coupling between the nominally separate coil elements can be a problem. In the case of birdcage coils, the elements are rungs that are connected by end rings, which promotes problematic coupling. Accordingly, multichannel coils tend to be of the transverse electromagnetic (TEM) configuration, in which each TEM element includes an elongate conductor connected at the ends with a radio frequency shield or screen that provides the return current path. Because the TEM elements are interconnected only by the radio frequency shield or screen which is an electrical ground plane, coupling between elements is substantially reduced.

However, inductive coupling between neighboring TEM elements remains problematic for some configurations and in some scanners. Approaches are known in the art for further reducing inductive coupling between the TEM elements.

In one approach, small coupling coils or loops are added next to each TEM element, and a pair of such coils or loops for any two neighboring TEM elements is connected via a transmission line. By suitable layout and adjustment, the mutual inductance of the TEM elements can be substantially canceled using this approach. However, the adjustment typically entails the use of variable reactances. These reactances and the decoupling coils or loops are components that add complexity to the TEM coil, and are not readily incorporated into the basic TEM coil layout. Moreover, the connections of the coils or loops introduce interdependencies that complicate the coil tuning process and can introduce other problems.

Another approach is to insert series connected compensation transformers between neighboring TEM elements. However, this approach undesirably increases the inductance of the TEM elements.

Another approach is to insert capacitive networks between reactive terminations of the TEM elements. By suitable selection of the capacitive coupling, inductive coupling between TEM elements can be substantially canceled. Again, the capacitive networks introduce undesirable complexity into the TEM coil and are difficult to adjust to achieve decoupling.

Accordingly, there remains an unfulfilled need in the art for improved multichannel TEM coils, and for improved methods for decoupling TEM elements.

### SUMMARY OF THE INVENTION

In accordance with certain illustrative embodiments shown and described as examples herein, a radio frequency coil is disclosed, comprising: a radio frequency screen; a plurality of operative transverse electromagnetic (TEM) elements defined by parallel elongate conductive elements coupled with the radio frequency screen and configured for operative connection with a multi-channel radio frequency driver; and a plurality of auxiliary elongate conductive elements each aligned to (i.e., parallel with) and disposed between two neighboring operative TEM elements and tuned to substantially decouple the two neighboring operative TEM elements.

In accordance with certain illustrative embodiments shown and described as examples herein, a radio frequency excitation system is disclosed, comprising: a transverse electromagnetic (TEM) coil including a radio frequency screen, a plurality of operative TEM elements defined by parallel elongate conductive elements coupled with the radio frequency screen, and a plurality of auxiliary elongate conductive elements each parallel with and disposed between two neighboring operative TEM elements and tuned to substantially decouple the two neighboring operative TEM elements; and a multichannel transmitter coupled with the TEM coil to drive each of the operative TEM elements independently from the other operative TEM elements or to drive each of a plurality of different groups of the operative TEM elements independently from the other groups of operative TEM elements.

In accordance with certain illustrative embodiments shown and described as examples herein, a magnetic resonance scanner is disclosed, comprising: a magnet generating a static (B₀) magnetic field; a magnetic field gradient system configured to superimpose magnetic field gradients on the static magnetic field; and a radio frequency excitation system as set forth in the immediately preceding paragraph.

In accordance with certain illustrative embodiments shown and described as examples herein, a magnetic resonance excitation method is disclosed, comprising: independently exciting a plurality of parallel operative transverse electromagnetic (TEM) elements to generate a radio frequency field in an examination region of a magnetic resonance scanner; and decoupling neighboring operative TEM elements of the plurality of parallel operative TEM elements using auxiliary elongate conductive elements each aligned to (i.e., parallel with) and disposed between two neighboring parallel operative TEM elements.

In accordance with certain illustrative embodiments shown and described as examples herein, a method is disclosed of decoupling operative transverse electromagnetic (TEM) elements of a multichannel TEM coil, the method comprising: disposing auxiliary conductive elements between neighboring operative TEM elements of the multichannel TEM coil to inductively couple with the neighboring operative TEM elements; and tuning the auxiliary conductive elements to decouple the operative TEM elements of the multichannel TEM coil.

One advantage resides in providing a multichannel TEM coil with improved decoupling between TEM elements.

Another advantage resides in providing improved methods for decoupling TEM elements.

Another advantage resides in providing simplified multichannel TEM coils.

Still further advantages of the present invention will be appreciated by those of ordinary skill in the art upon reading and understand the following detailed description.

### BRIEF DESCRIPTION OF THE DRAWINGS

These and other aspects will be described in detail hereinafter, by way of example, on the basis of the following embodiments, with reference to the accompanying drawings, wherein:

FIG. 1 diagrammatically shows a magnetic resonance scanner system;

FIG. 2 diagrammatically shows a perspective view of a multi-channel TEM coil with intervening decoupling TEM elements suitable for use in the scanner system of FIG. 1;

FIG. 3 diagrammatically shows a perspective view of a portion of the multi-channel TEM coil of FIG. 2 including two neighboring operative TEM elements and an intervening decoupling TEM element including an elongated strip conductor. The portion of the cylindrical coil of FIG. 2 shown in FIG. 3 is shown substantially unrolled or flattened for illustrative convenience;

FIG. 4 diagrammatically shows a perspective view of a portion of an alternative TEM coil, the perspective view showing two neighboring operative TEM elements and an intervening decoupling TEM element including an elongated rod conductor;

FIG. 5 diagrammatically shows a perspective view of a portion of an alternative TEM coil, the perspective view showing two neighboring operative TEM elements and an intervening decoupling TEM element including an elongated double-rod conductor;

FIG. 6 diagrammatically shows a perspective view of a portion of an alternative TEM coil, the perspective view showing two neighboring operative TEM elements and an intervening decoupling element including an elongated conductive loop;

FIG. 7 diagrammatically shows a perspective view of a portion of an alternative TEM coil, the perspective view showing two neighboring operative TEM elements and an intervening decoupling TEM element including a combination of an elongated conductive loop and an elongated conductive rod; and

FIG. 8 diagrammatically shows a perspective view of a portion of an alternative TEM coil, the perspective view showing two neighboring operative TEM elements and an intervening decoupling element including two elongated strips each operatively coupled at its ends with one of the operative TEM elements.

Corresponding reference numerals when used in the various figures represent corresponding elements in the figures.

### DETAILED DESCRIPTION OF EMBODIMENTS

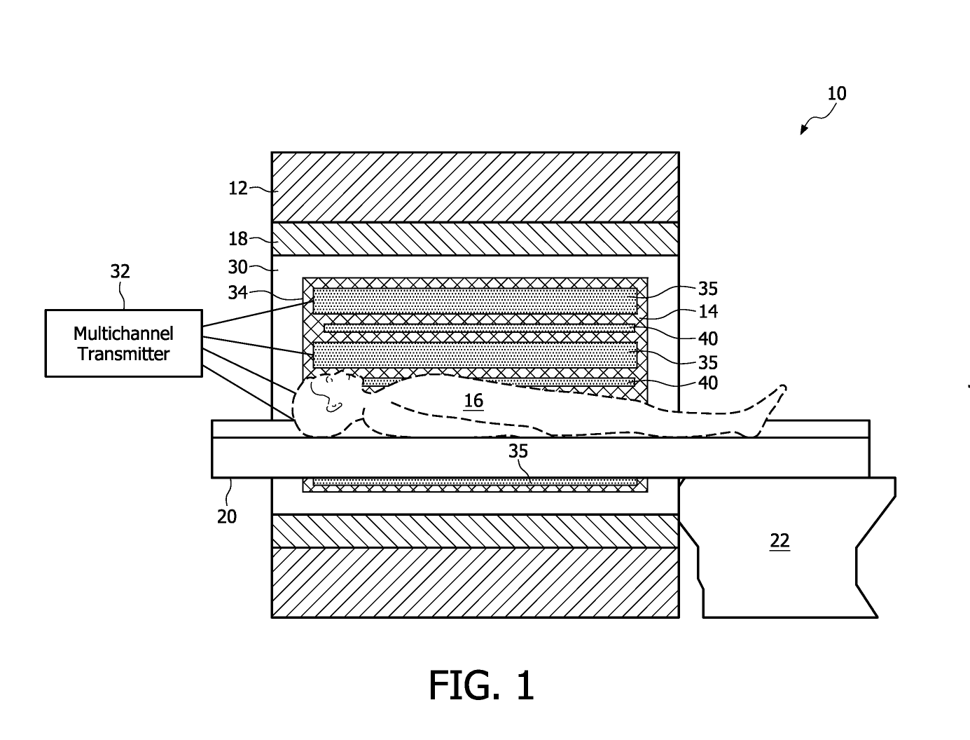

With reference to FIG. 1, a magnetic resonance scanner 10 includes a main magnet 12 generating a static (B₀) magnetic field in an examination region 14 in which is disposed a subject 16 (shown in phantom in FIG. 1). The illustrated magnetic resonance scanner 10 is a horizontal bore-type scanner shown in cross-section to reveal selected components; however, other types of magnetic resonance scanners can be used. The magnetic resonance scanner 10 is optionally a high-field scanner in which the main magnet 12 produces the static (B₀) magnetic field in the examination region 14 at a magnetic field strength greater than or about 3 Tesla, and in some embodiments greater than or about 5 Tesla. In some embodiments, the main magnet 12 produces a static (B₀) magnetic field in the examination region 14 at a magnetic field strength of 7 Tesla. Higher or lower magnetic field strengths are also contemplated.

The magnetic resonance scanner 10 also includes a magnetic field gradient system 18 that superimposes selected magnetic field gradients on the static (B₀) magnetic field to perform various tasks such as spatially restricting magnetic resonance excitation, spatially encoding magnetic resonance frequency and/or phase, spoiling magnetic resonance, or so forth. In some embodiments, the magnetic field gradient system 18 includes a plurality of coils configured and arranged to generate selected magnetic field gradients in three orthogonal directions, e.g. in x-, y-, and z-directions. Optionally, the magnetic resonance scanner may include other elements not shown in FIG. 1, such as a bore liner, active coil or passive ferromagnetic shims, or so forth. The subject 16 is suitably prepared by being placed on a movable subject support 20 which is then inserted along with the supported subject 16 into the illustrated position for magnetic resonance data acquisition. For example, the subject support 20 may be a pallet or table that is initially disposed on a couch 22 adjacent the magnetic resonance scanner 10, the subject 16 placed onto the support 20 and then slidably transferred from the couch 22 into the bore of the magnetic resonance scanner 10.

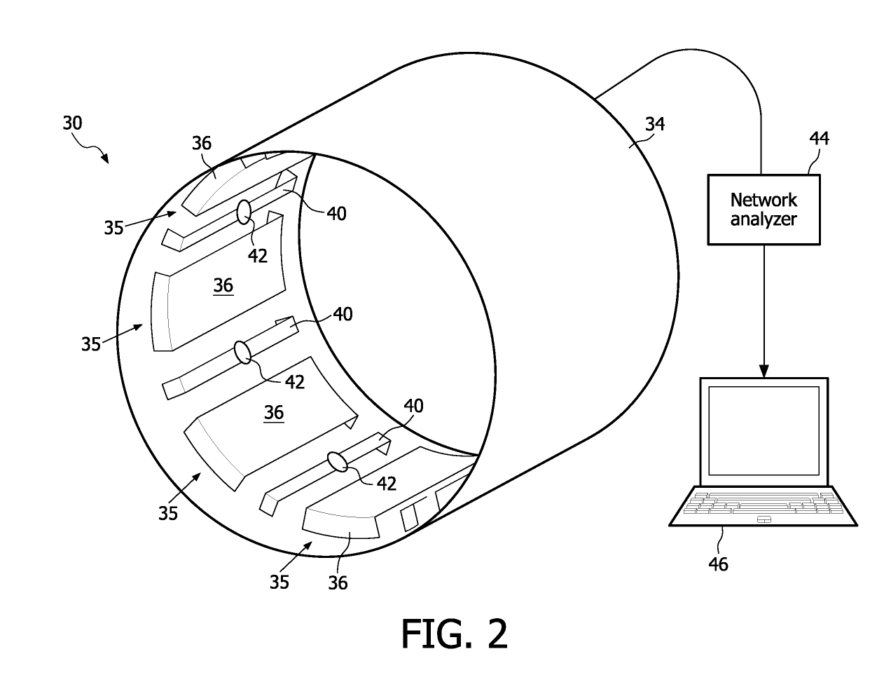

With continuing reference to FIG. 1 and with further reference to FIG. 2, a multichannel transverse electromagnetic (TEM) coil 30 is excited by a multichannel transmitter 32 to excite magnetic resonance in a selected region of the subject 16. Optionally, the TEM coil 30 is also used to receive magnetic resonance signals using a receiver (not shown) that is capable of being switchably coupled to the TEM coil 30, or alternatively separate receive coils can be provided (not shown) in the form of a surface coil or other local coil. The illustrated multichannel TEM coil 30 is a whole-body coil having a generally cylindrical shape positioned substantially coaxially with the bore of the magnetic resonance scanner 10. In other embodiments, the multichannel TEM coil connected with the multichannel transmitter 32 may be a local coil such as a head coil, limb coil, or so forth.

The illustrated multichannel TEM coil 30 includes a radio frequency shield or screen 34 and a plurality of operative TEM elements 35 defined by parallel elongate conductive elements 36 coupled with the radio frequency screen 34 at or near the ends of the elongate conductive elements 36. The elongate conductive elements 36 are configured for operative connection with the multi-channel radio frequency transmitter or driver 32. In some embodiments, each TEM element 35 defined by one of the elongate conductive elements 36 is independently driven by a dedicated channel of the multi-channel radio frequency transmitter or driver 32. In other embodiments, the TEM elements 35 may be arranged electrically into two, three, four, or more groups each including two or more of the elongate conductive elements 36, with each group being suitably driven independently by a channel of the multi-channel radio frequency transmitter or driver 32. By suitably independently exciting the plurality of parallel TEM elements 35, a substantially spatially uniform radio frequency field can be generated in the examination region 14 of the magnetic resonance scanner 10, even at high magnetic field strength and in the case of subject loading. The radio frequency screen 34 of the illustrated TEM coil 30 has a cylindrical shape with a circular cross-section. However, a cylindrical radio frequency screen with an elliptical, non-radially symmetric, or other cross-section is also contemplated. Moreover, it is contemplated for the radio frequency screen to not define a closed loop.

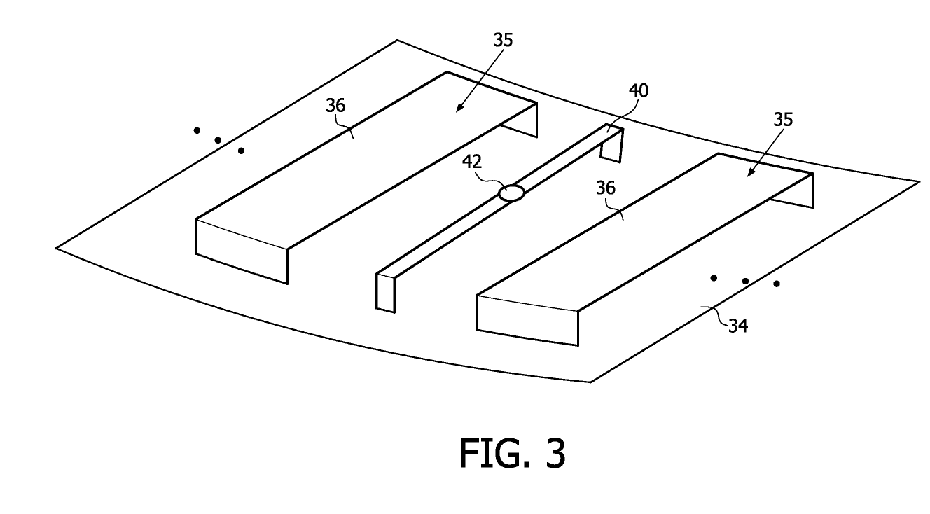

With continuing reference to FIGS. 1 and 2 and with further reference to FIG. 3, for efficient multi-channel operation, it is desirable for the operative TEM elements defined by the parallel elongate conductive elements 36 coupled with the radio frequency screen 34 to be decoupled from each other. To achieve this, a plurality of auxiliary elongate conductive elements 40 are arranged each parallel with and disposed centrally between two neighboring operative TEM elements 35. Each of the auxiliary elongate conductive elements 40 is coupled with the radio frequency screen 34 to define an auxiliary TEM element tuned to substantially decouple the two neighboring operative TEM elements 35. The auxiliary element should be tuned to carry current effective enough to block mutual coupling current from flowing in the neighboring operative TEM elements 35.

The illustrated auxiliary elongate conductive elements 40 are similar to the operative TEM elements 35 in length and separation from the radio frequency screen 34; however, auxiliary elongated conductive elements that are substantially longer, shorter, or differently spaced from the screen 34 as compared with the operative TEM elements 35 are also contemplated. The illustrated auxiliary elongate conductive elements 40 are less wide than the parallel elongate conductive elements 36 of the operative TEM elements 35, although again other geometries are also contemplated, including auxiliary elongate conductive elements embodied as strips wider than strips of the operative TEM elements. By tuning the auxiliary decoupling TEM elements defined by the auxiliary elongate conductive elements 40 to a suitable resonance frequency below the intended operational frequency (that is, the magnetic resonance frequency of interest) of the multichannel TEM coil 30, the coupling between neighboring TEM elements 35 can be substantially suppressed.

Although not shown, the multichannel TEM coil 30 can include other components known in the art, such as tuning capacitances for the parallel elongate conductive elements 36 of the operative TEM elements 35, detuning circuitry, impedance matching circuitry, or so forth.

With reference to FIGS. 2 and 3, in one suitable approach each auxiliary elongate conductive element 40 includes an adjustable tuning capacitance 42. The auxiliary TEM elements defined by the auxiliary elongate conductive elements 40 are generally inductive, and the adjustable tuning capacitances 42 enable adjustably tuned partial cancelation of this inductance to tune the reactance of the auxiliary TEM elements to substantially decouple the two neighboring operative TEM elements 35. In one illustrative tuning approach, resonance of neighboring operative TEM elements 35 of the multichannel TEM coil 30 is monitored using a network analyzer 44 outputting a display on a suitable user interface 46 (shown as a separate component in FIG. 2 but optionally integral with the network analyzer 44), and the adjustable tuning capacitances 42 of the auxiliary elongate conductive elements 40 are adjusted to eliminate resonance splitting (of the monitored resonance) caused by coupling of neighboring TEM elements. The tuned resonance frequency of the auxiliary TEM elements is also optionally checked to ensure that it is not at a resonance frequency likely to interfere with scanner electronics or other components operating at radio frequencies. As an illustrative example, in one actually constructed 7 Tesla multichannel TEM coil using auxiliary strip conductors 40 similar to that of FIG. 3, in which the multichannel TEM coil was tuned to 298 MHz (that is, tuned to the ¹H magnetic resonance frequency at 7 Tesla), it was found that tuning the auxiliary TEM elements defined by the auxiliary strip conductors to a resonance frequency of about 230 MHz provided effective decoupling of the operative TEM elements of the 7 Tesla multichannel TEM coil.

The described decoupling procedure employing the network analyzer 44 is not done by tuning the auxiliary TEM-elements to a pre-determined frequency, but rather by looking at the transfer function of operative TEM elements 35 with the network analyzer 44 and changing the value of a variable or adjustable capacitances 42 in the auxiliary elongated conductive elements 40 until an initially observed resonance split vanishes. In one suitable approach, the operative TEM elements 35 are tuned separately to the frequency of the MR system. Then two neighboring operative TEM elements 35 and the intervening decoupling auxiliary elongate conductive element 40 as a decoupling element are made operational and all other operative TEM elements and auxiliary elements are disabled (that is, electrically open-circuited). The first pair of TEM elements is then decoupled by adjusting the capacitance 42 in the auxiliary element until the resonance split observed in one of the TEM elements vanishes. Then the other neighboring operative TEM element of the monitored element and the corresponding auxiliary element are made operational and the capacitor in that auxiliary element is adjusted for minimization or removal of the resonance split. The adjustment of the first auxiliary strip's capacitor may entail a small correction. Then this procedure is repeated by enabling the next neighboring operational TEM and auxiliary element and monitoring the one previously enabled until all pairs have been enabled. When the coil chain forms a closed loop such as in the cylindrical coil 30 illustrated in FIG. 2, the first auxiliary element's capacitor receives a final readjustment. A final “round-trip” of making fine adjustments of the TEM element resonances and the decoupler capacitor settings may provide further improvement. However, a single pass is sometimes sufficient to provide decoupling, in which case such further iterations of the procedure are optionally omitted.

In contrast, it is known that capacitive decoupling networks and the like that include wired electrical connections or other close connections between decoupling components tend to exhibit a high degree of mutual coupling, such that tuning the decoupling network to achieve a substantially decoupled multichannel TEM coil is a tedious, iterative, time-consuming process. Although the described tuning process employs the network analyzer 44 and does not directly reference the resonance frequencies of the auxiliary elongate conductive elements, it is also contemplated to employ other decoupling processes such as monitoring the resonance frequencies of the auxiliary elongate conductive elements during the decoupling.

In some embodiments, such as the illustrated cylindrical multichannel TEM coil 30 having the circular cross-section shown in FIG. 2, the radio frequency screen 34 defines a closed loop, the plurality of TEM elements 35 comprise N TEM elements and N pairs of neighboring TEM elements due to the multichannel TEM coil being a closed loop, and the plurality of auxiliary elongate conductive elements 40 comprise N auxiliary elongate conductive elements, there being one auxiliary elongate conductive element disposed between each pair of neighboring TEM elements. In general, as used herein, N is an integer greater than or equal to four corresponding to the number of TEM elements of the multichannel TEM coil.

In some contemplated embodiments, the multichannel TEM coil is not a closed loop, but rather is an open loop. In such embodiments, the operative TEM elements do not form a closed loop, and so the N TEM elements define (N−1) pairs of neighboring TEM elements. Accordingly, in such embodiments, (N−1) auxiliary elongate conductive elements are suitably employed to decouple the operative TEM elements of the multichannel TEM coil.

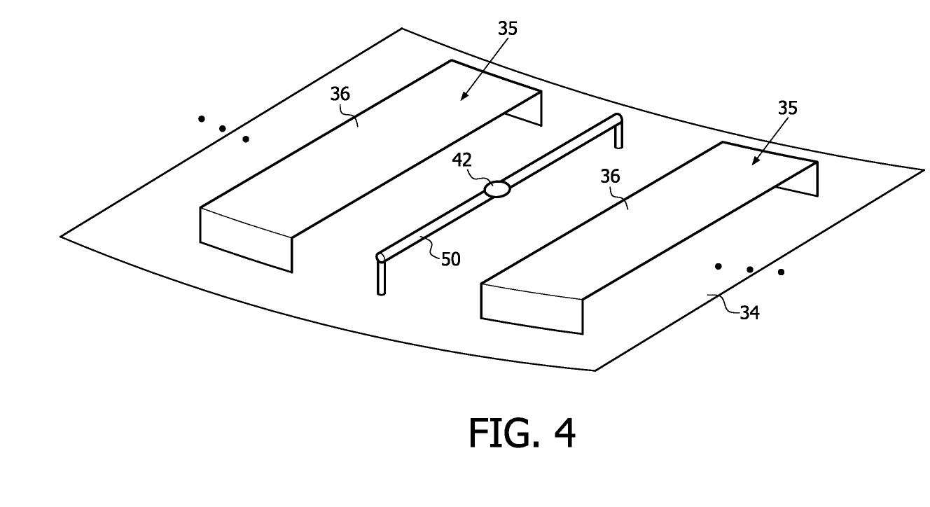

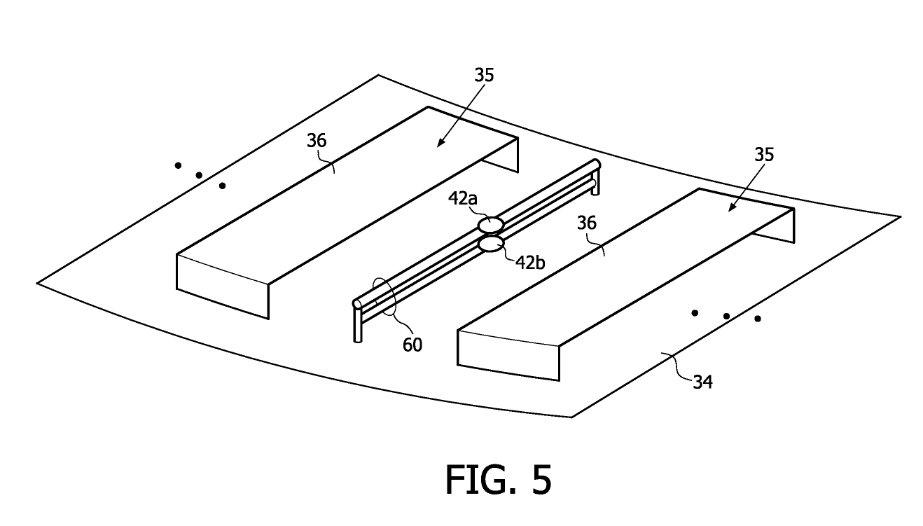

With reference to FIGS. 4 to 8, the auxiliary elongate conductive elements, each arranged parallel with and disposed centrally between two neighboring operative TEM elements and tuned to substantially decouple the two neighboring operative TEM elements can be variously embodied. FIGS. 4-8 show further illustrative embodiments. FIG. 4 shows an auxiliary elongate conductive element embodied as an elongated rod 50 connected at or near the ends with the radio frequency screen 34 to define an auxiliary TEM element, and having a resonance adjustable using the adjustable tuning capacitance 42. FIG. 5 shows an auxiliary elongate conductive element embodied as an elongated double-rod 60 connected at or near the ends with the radio frequency screen 34 to define an auxiliary TEM element. In the embodiment illustrated in FIG. 5, each component rod has an associated adjustable tuning capacitance 42a, 42b for tuning. The use of the double-rod 60 with individual adjustable tuning capacitances 42a, 42b permits more precisely tuned decoupling of the neighboring operative TEM elements 35.

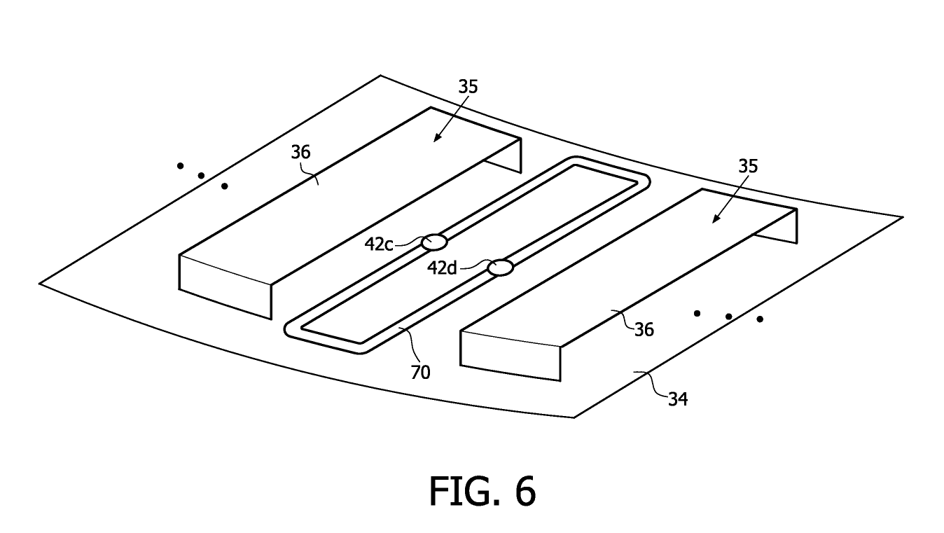

FIG. 6 shows an auxiliary elongate conductive element embodied as an elongated conductive loop 70 that is electrically floating. The auxiliary elongate conductive element embodied as the elongated conductive loop 70 is not connected with the radio frequency screen 34 to define an auxiliary TEM element. Each elongate conductive loop 70 defines a loop plane parallel with a plane containing the two neighboring operative TEM elements 35. Another way of specifying the orientation of the loops 70 of FIG. 6 is to say that the loop plane is parallel with the proximate portion of the radio frequency screen 34. In the embodiment shown in FIG. 6, effective decoupling is achieved by tuning the elongated conductive loop 70, using one or more adjustable tuning capacitances 42c, 42d inserted into the conductive loop 70, to a resonance frequency that is higher than the magnetic resonance frequency to which is tuned the multichannel TEM coil. The precise tuning for decoupling can be empirically determined using the network analyzer 44 and display 46 of FIG. 2. In the embodiment shown in FIG. 6, the length of the elongated conductive loop 70 is similar to the length of the operative TEM elements 35.

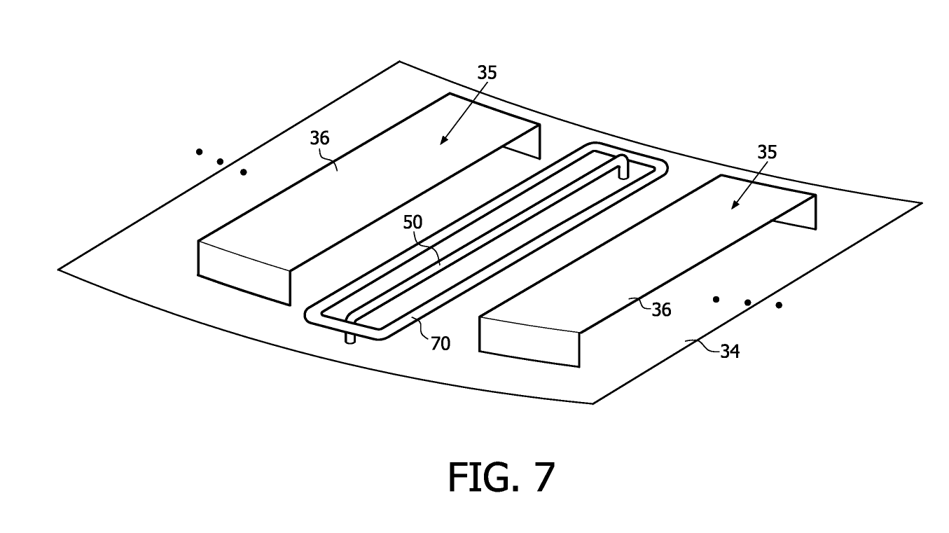

FIG. 7 shows an embodiment in which the auxiliary elongate conductive element is embodied as a combination of the elongated rod 50 of FIG. 4 and the elongated conductive loop 70 of FIG. 6. The elongated rod 50 defines an auxiliary TEM element, while the elongated conductive loop 70 is electrically floating. Accordingly, the composite auxiliary elongate conductive element 50, 70 as shown in FIG. 7 is a combination of a TEM element and a floating elongated conductive loop that are decoupled from each other by symmetry. Although not shown, various arrangements of one or more adjustable tuning capacitances can be included in the elongated rod 50, the elongated conductive loop 70, or both.

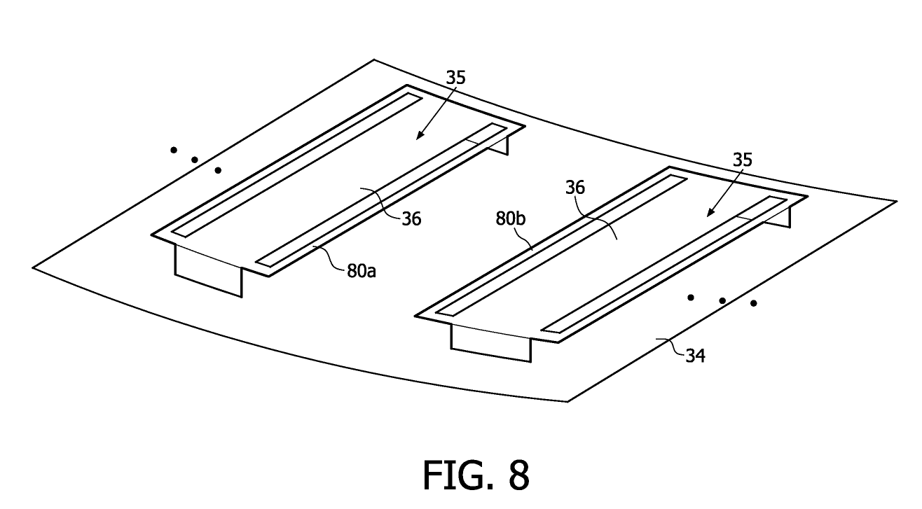

FIG. 8 shows an embodiment in which the auxiliary elongate conductive element is embodied as first and second parallel elongate conductive elements 80a, 80b disposed between neighboring TEM elements 35. The first elongate conductive element 80a is spaced apart from and parallel with a proximate one of the neighboring operative TEM elements 35 and is coupled therewith proximate to its ends. The second elongate conductive element 80b is spaced apart from and parallel with a different proximate one of the neighboring operative TEM elements 35 and is coupled therewith proximate to its ends. Although not shown, adjustable tuning capacitances can be incorporated into the elongate conductive elements 80a, 80b to enable tuning of the composite auxiliary elongate conductive element 80a, 80b to decouple the neighboring operative TEM elements 35.

It is to be appreciated that in some embodiments one, some, or all of the adjustable tuning capacitances 42, 42a, 42b, 42c, 42d may be replaced by fixed or unadjustable tuning capacitances having fixed values suitable for achieving the desired resonance frequency for achieving decoupling. The auxiliary elongated conductive elements have numerous advantages, including for example advantageous symmetry, distribution of the decoupling along the lengths of the TEM elements, a good geometric fit of the auxiliary elongated conductive elements in the existing elongated gaps between TEM elements of a multichannel TEM coil, and so forth.

The invention has been described with reference to the preferred embodiments. Modifications and alterations may occur to others upon reading and understanding the preceding detailed description. It is intended that the invention be construed as including all such modifications and alterations insofar as they come within the scope of the appended claims or the equivalents thereof. In the claims, any reference signs placed between parentheses shall not be construed as limiting the claim. The word “comprising” does not exclude the presence of elements or steps other than those listed in a claim. The word “a” or “an” preceding an element does not exclude the presence of a plurality of such elements. The disclosed method can be implemented by means of hardware comprising several distinct elements, and by means of a suitably programmed computer. In the system claims enumerating several means, several of these means can be embodied by one and the same item of computer readable software or hardware. The mere fact that certain measures are recited in mutually different dependent claims does not indicate that a combination of these measures cannot be used to advantage.

1. A radio frequency coil comprising:
a radio frequency screen (34);
a plurality of operative transverse electromagnetic (TEM) elements (35) defined by parallel elongate conductive elements (36) coupled with the radio frequency screen and configured for operative connection with a multi-channel radio frequency driver (32); and
a plurality of auxiliary elongate conductive elements (40, 50, 60, 70, 80a, 80b) each parallel with and disposed between two neighboring operative TEM elements and tuned to substantially decouple the two neighboring operative TEM elements.

2. The radio frequency coil as set forth in claim 1, wherein the radio frequency screen (34) defines a closed loop, the plurality of operative TEM elements (35) comprise N operative TEM elements and N pairs of neighboring operative TEM elements, and the plurality of auxiliary elongate conductive elements (40, 50, 60, 70, 80a , 80b) comprise N auxiliary elongate conductive elements, there being one auxiliary elongate conductive element disposed between and parallel to each pair of neighboring TEM elements.

3. The radio frequency coil as set forth in claim 1, wherein the plurality of auxiliary elongate conductive elements (40, 50, 60, 70, 80a, 80b) comprise:
an elongate conductive element (40, 50, 60) disposed between two neighboring operative TEM elements (35) and coupled with the radio frequency screen (34) to define an auxiliary TEM element tuned to substantially decouple the two neighboring operative TEM elements.

4. The radio frequency coil as set forth in claim 3, wherein the elongate conductive element (40, 50, 60) has a length about equal to lengths of the operative TEM elements (35).

5. The radio frequency coil as set forth in claim 1, wherein the plurality of auxiliary elongate conductive elements (40, 50, 60, 70, 80a, 80b) comprise:
an elongate conductive loop (70) disposed between two neighboring operative TEM elements (35) and tuned to substantially decouple the two neighboring operative TEM elements.

6. The radio frequency coil as set forth in claim 5, wherein the elongate conductive loop (70) has a length in the direction of elongation about equal to a length of the neighboring TEM elements (35).

7. The radio frequency coil as set forth in claim 1, wherein the plurality of auxiliary elongate conductive elements (40, 50, 60, 70, 80a, 80b) comprise:
an elongate conductive loop (70) disposed between two neighboring operative TEM elements (35) and tuned to substantially decouple the two neighboring operative TEM elements, the elongate conductive loop defining a loop plane parallel with a plane containing the two neighboring operative TEM elements.

8. The radio frequency coil as set forth in claim 1, wherein the plurality of auxiliary elongate conductive elements (40, 50, 60, 70, 80a, 80b) comprise:
first and second parallel elongate conductive elements (80a, 80b) disposed between first and second neighboring TEM elements (35) and tuned to substantially decouple the two neighboring operative TEM elements;
the first elongate conductive element (80a) spaced apart from and parallel with the first neighboring operative TEM element and coupled with the first neighboring operative TEM element proximate to its ends; and
the second elongate conductive element (80b) spaced apart from and parallel with the second neighboring operative TEM element and coupled with the second neighboring operative TEM element proximate to its ends.

9. The radio frequency coil as set forth in claim 8, wherein the radio frequency coil is cylindrical and each operative TEM element (35) has coupled therewith proximate to its ends on one side one of the first elongate conductive elements (80a) and has coupled therewith proximate to its ends on an opposite side one of the second elongate conductive elements (80b).

10. A magnetic resonance system comprising:
a main magnet (12) for generating a main magnetic field (B₀); and
a radio frequency coil as set forth in claim 1.

11. A radio frequency excitation system including:
the radio frequency coil as set forth in claim 1; and
a multichannel transmitter (32) coupled with the TEM coil to drive each of the operative TEM elements independently from the other operative TEM elements or to drive each of a plurality of different groups of the operative TEM elements independently from the other groups of operative TEM elements.

12. A magnetic resonance excitation method comprising:
independently exciting a plurality of parallel operative transverse electromagnetic (TEM) elements (35) to generate a radio frequency field in an examination region (14) of a magnetic resonance scanner (10); and
decoupling neighboring operative TEM elements of the plurality of parallel operative TEM elements using auxiliary conductive elements (40, 50, 60, 70, 80a, 80b) each parallel with and disposed between two neighboring parallel operative TEM elements.

13. The magnetic resonance excitation method as set forth in claim 12, further comprising:
prior to the exciting, tuning the auxiliary conductive elements (40, 50, 60, 70, 80a, 80b) to decouple the neighboring parallel operative TEM elements (35).

14. The magnetic resonance excitation method as set forth in claim 13, wherein the tuning comprises:
monitoring resonance of neighboring parallel operative TEM elements (35) using a network analyzer (44); and
tuning the auxiliary conductive elements (40, 50, 60, 70, 80a , 80b) to eliminate resonance splitting of the monitored resonance caused by coupling of neighboring parallel operative TEM elements.

15. The magnetic resonance excitation method as set forth in claim 13, wherein the auxiliary conductive elements are elongated parallel with the operative TEM elements (35), and the tuning comprises:
adjusting capacitances (42, 42a, 42b, 42c, 42d) of the elongated auxiliary conductive elements (40, 50, 60, 70, 80a, 80b) to decouple the neighboring parallel operative TEM elements (35).
